(19) United States
(12) Patent Application Publication
(10) Pub. No.: US 2024/0324313 A1
(43) Pub. Date: Sep. 26, 2024

(54) DISPLAY APPARATUS

(71) Applicant: Samsung Display Co., Ltd., Yongin-Si (KR)

(72) Inventors: Hyunho Kim, Yongin-si (KR); Hyoengki Kim, Yongin-si (KR); Taehoon Yang, Yongin-si (KR)

(21) Appl. No.: 18/605,818

(22) Filed: Mar. 15, 2024

(30) Foreign Application Priority Data
Mar. 24, 2023 (KR) 10-2023-0039252
Apr. 14, 2023 (KR) 10-2023-0049597

(51) Int. Cl. H10K 59/122; H10K 59/80

(52) U.S. Cl. CPC H10K 59/122; H10K 59/80515; H10K 59/8792

(57) ABSTRACT

A display apparatus includes a pixel circuit layer including at least one thin-film transistor, a planarization layer located on the at least one thin-film transistor, and a first bank layer located on the planarization layer and defining a first opening, a display element including a pixel electrode located to correspond to the first opening, a counter electrode, and an emission layer located between the pixel electrode and the counter electrode, a second bank layer located between the pixel electrode and the counter electrode defining a pixel opening, and a light-blocking layer located on the display element and defining a second opening, wherein the pixel electrode includes an inclined surface located on a side surface of the first bank layer and a flat surface located on a top surface of the planarization layer exposed through the first opening, wherein the inclined surface of the pixel electrode is inclined by 15° to 25°.

### CROSS-REFERENCE TO RELATED APPLICATION

This application is based on and claims priority under 35 U.S.C. § 119 to Korean Patent Application Nos. 10-2023-0039252 and 10-2023-0049597, respectively filed on Mar. 24, 2023, and Apr. 14, 2023, in the Korean Intellectual Property Office, the disclosures of which are incorporated by reference herein in their entirety.

### BACKGROUND

### 1. Field

One or more embodiments relate to a display apparatus.

### 2. Description of the Related Art

Mobility-based mobile electronic devices are widely used. Tablet personal computers (PCs), in addition to small electronic devices such as mobile phones, are widely used as mobile electronic devices.

A mobile electronic device includes a display apparatus for providing visual information such as an image to a user in order to support various functions. Recently, the proportion of a display apparatus in an electronic device has gradually increased, and structures that are bendable by certain angles have been developed.

### SUMMARY

When a display apparatus is viewed in a direction oblique to a front surface of the display apparatus, not only a luminance of the display apparatus rapidly decreases but also a color change occurs, thereby degrading the quality of an image. One or more embodiments include a display apparatus capable of providing a high-quality image even when viewed in a direction oblique to a front surface of the display apparatus. However, the embodiments are examples, and do not limit the scope of the disclosure.

Additional aspects will be set forth in part in the description which follows and, in part, will be apparent from the description, or may be learned by practice of the presented embodiments.

According to one or more embodiments, a display apparatus includes a substrate, a pixel circuit layer located on the substrate and including at least one thin-film transistor, a planarization layer located on the at least one thin-film transistor, and a first bank layer located on the planarization layer and defining a first opening, a display element including a pixel electrode located to correspond to the first opening, a counter electrode, and an emission layer located between the pixel electrode and the counter electrode, a second bank layer located between the pixel electrode and the counter electrode to cover an edge of the pixel electrode and defining a pixel opening overlapping the first opening, and a light-blocking layer located on the display element and defining a second opening overlapping the pixel opening, wherein the pixel electrode includes an inclined surface located on a side surface of the first bank layer defining the first opening and a flat surface located on a top surface of the planarization layer exposed through the first opening, wherein the inclined surface of the pixel electrode is inclined by 15° to 25° with respect to the flat surface of the pixel electrode.

In a plan view, a distance between a boundary of the inclined surface of the pixel electrode and a boundary of the flat surface of the pixel electrode may range from 1 μm to 5 μm.

A thickness of the first bank layer may range from 0.5 μm to 2.3 μm.

A width of the second opening may be the same as a width of the pixel opening.

The display apparatus may further include a color filter layer located on the display element to correspond to the second opening.

According to one or more embodiments, a display apparatus includes a substrate, a pixel circuit layer located on the substrate and including at least one thin-film transistor, a planarization layer located on at least one thin-film transistor, and a first bank layer located on the planarization layer and defining a 1-1^{th} opening, a first display element including a first pixel electrode located to correspond to the 1-1^{th} opening, a counter electrode, and a first emission layer located between the first pixel electrode and the counter electrode, a second display element spaced apart from the first pixel electrode, and including a second pixel electrode, the counter electrode, and a second emission layer located between the second pixel electrode and the counter electrode, a second bank layer covering an edge of each of the first pixel electrode and the second pixel electrode and defining a first pixel opening corresponding to the first pixel electrode and a second pixel opening corresponding to the second pixel electrode, and a light-blocking layer located on the first display element and the second display element, and defining a 2-1^{th} opening overlapping the first pixel opening and a 2-2^{th} opening overlapping the second pixel opening, wherein the first pixel electrode includes an inclined surface located on a side surface of the first bank layer defining the 1-1^{th} opening and a flat surface located on a top surface of the planarization layer exposed through the 1-1^{th} opening, and wherein the inclined surface of the first pixel electrode is inclined by 15° to 25° with respect to the flat surface of the first pixel electrode.

In a plan view, a distance between a boundary of the inclined surface of the first pixel electrode and a boundary of the flat surface of the first pixel electrode may range from 1 μm to 5 μm.

A thickness of the first bank layer may range from 0.5 μm to 2.3 μm.

A width of the 2-1^{th} opening may be same as a width of the first pixel opening.

The first bank layer may further define a 1-2^{th} opening corresponding to the second pixel electrode, wherein the second pixel electrode includes an inclined surface located on a side surface of the first bank layer defining the 1-2^{th} opening and a flat surface located on a top surface of the planarization layer exposed through the 1-2^{th} opening.

In a plan view, a 1-1^{th} distance between a boundary of the inclined surface of the first pixel electrode and a boundary of the flat surface of the first pixel electrode may be different from a 1-2^{th} distance between a boundary of the inclined surface of the second pixel electrode and a boundary of the flat surface of the second pixel electrode.

In a plan view, the 1-2^{th} distance between the boundary of the inclined surface of the second pixel electrode and the boundary of the flat surface of the second pixel electrode may range from 1 μm to 5 μm.

A width of the 2-2^{th} opening may be same as a width of the second pixel opening.

According to one or more embodiments, a display apparatus includes a substrate, a pixel circuit layer located on the substrate and including at least one thin-film transistor, a planarization layer located on the at least one thin-film transistor, and a first bank layer located on the planarization layer and defining a 1-1^{th} opening, a first display element including a first pixel electrode located to correspond to the 1-1^{th} opening, a counter electrode, and a first emission layer located between the first pixel electrode and the counter electrode, a second display element located on the planarization layer to be spaced apart from the first pixel electrode, the second display element including a second pixel electrode, the counter electrode, and a second emission layer located between the second pixel electrode and the counter electrode, a second bank layer covering an edge of each of the first pixel electrode and the second pixel electrode and defining a first pixel opening corresponding to the first pixel electrode and a second pixel opening corresponding to the second pixel electrode, and a light-blocking layer located on the first display element and the second display element, and defining a 2-1^{th} opening overlapping the first pixel opening and a 2-2^{th} opening overlapping the second pixel opening, wherein the first pixel electrode includes an inclined surface located on a side surface of the first bank layer defining the 1-1^{th} opening and a flat surface located on a top surface of the planarization layer exposed through the 1-1^{th} opening, and the second pixel electrode includes only a flat surface located on a top surface of the planarization layer.

The inclined surface of the first pixel electrode may be inclined by 15° to 25° with respect to the flat surface of the first pixel electrode.

In a plan view, a distance between a boundary of the inclined surface of the first pixel electrode and a boundary of the flat surface of the first pixel electrode may range from 1 μm to 5 μm.

A thickness of the first bank layer may range from 0.5 μm to 2.3 μm.

A width of the 2-1^{th} opening may be same as a width of the first pixel opening.

The first bank layer may be spaced apart from the second pixel electrode.

A width of the 2-2^{th} opening may be greater than a width of the second pixel opening.

Other aspects, features, and advantages of the disclosure will become more apparent from the drawings, the claims, and the detailed description.

### BRIEF DESCRIPTION OF THE DRAWINGS

The above and other aspects, features, and advantages of certain embodiments will be more apparent from the following description taken in conjunction with the accompanying drawings, in which:

FIG. 1 is a perspective view schematically illustrating a display apparatus, according to an embodiment;

FIG. 2 is a cross-sectional view schematically illustrating the display apparatus, according to an embodiment;

FIG. 3 is an equivalent circuit diagram schematically illustrating a sub-pixel included in a display apparatus, according to an embodiment;

FIG. 4 is a plan view schematically illustrating a display apparatus, according to an embodiment;

FIG. 5 is a cross-sectional view schematically illustrating a display apparatus, according to an embodiment;

FIGS. 6 and 7 are enlarged cross-sectional views illustrating a portion A of the display apparatus of FIG. 5;

FIG. 8 is a graph illustrating a change in white color coordinates of a conventional display apparatus according to a change in a viewing angle;

FIG. 9 is a graph illustrating a change in a luminance of sub-pixels, in which a pixel electrode has only a flat surface, according to a change in a viewing angle;

FIG. 10 is a cross-sectional view schematically illustrating a display apparatus, according to an embodiment;

FIG. 11 is a cross-sectional view schematically illustrating a display apparatus, according to an embodiment; and

FIG. 12 is a graph illustrating a simulation result of a change in white color coordinates of display apparatuses according to a change in a viewing angle.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

While such terms as “first,” “second,” etc., may be used to describe various components, such components are not be limited to the above terms. The above terms are used only to distinguish one component from another.

The singular forms “a,” “an,” and “the” as used herein are intended to include the plural forms as well unless the context clearly indicates differently.

It will be further understood that the terms “comprises” or “comprising” used herein specify the presence of stated features or components, but do not preclude the presence or addition of one or more other features or components.

It will be further understood that, when a layer, region, or component is referred to as being “on” another layer, region, or component, it may be directly on the other layer, region, or component, or may be indirectly on the other layer, region, or component with intervening layers, regions, or components therebetween.

In the specification, it will be understood that when a layer, a region, or a component is referred to as being “connected” to another layer, region, or component, it may be “directly connected” to the other layer, region, or component and/or may be “indirectly connected” to the other layer, region, or component with other layers, regions, or components interposed therebetween. For example, when a layer, a region, or a component is referred to as being “electrically connected” to another layer, region, or component, it may be directly electrically connected to the other layer, region, or component, and/or may be indirectly electrically connected to the other layer, region, or component with intervening layers, regions, or components therebetween.

“A and/or B” is used herein to select only A, select only B, or select both A and B. “At least one of A and B” is used to select only A, select only B, or select both A and B.

The x-axis, the y-axis and the z-axis used herein are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment in the disclosure may be implemented differently, a specific process order may be different from the described order. For example, two consecutively described processes may be performed substantially at the same time or may be performed in an order opposite to the described order.

Sizes of components in the drawings may be exaggerated or reduced for convenience of explanation. For example, because sizes (e.g., thicknesses) of elements in the drawings are arbitrarily illustrated for convenience of explanation, the disclosure is not limited thereto.

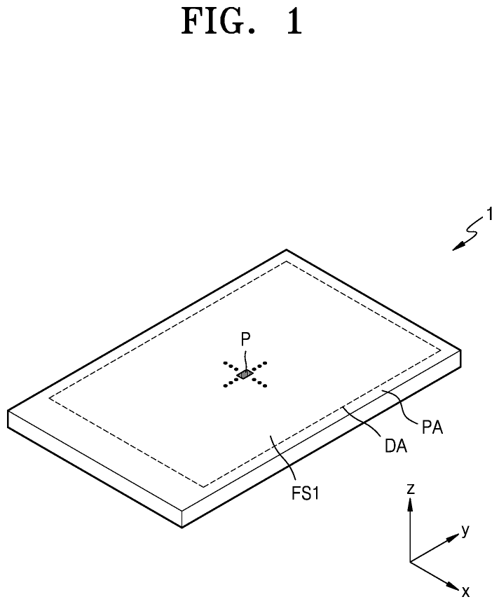

FIG. 1 is a perspective view schematically illustrating a display apparatus, according to an embodiment.

Referring to FIG. 1, a display apparatus 1 may include a display area DA and a peripheral area PA. A sub-pixel P may be located in the display area DA. In an embodiment, the sub-pixel P may be located on a front surface FS1 of the display apparatus 1.

In an embodiment, a plurality of sub-pixels P may be located in the display area DA. The sub-pixel P may be implemented as a display element. The display apparatus 1 may provide an image by using light emitted by the plurality of sub-pixels P. In an embodiment, light emitted by the sub-pixel P may travel in a direction (e.g., a z direction) perpendicular to the front surface FS1 of the display apparatus 1 and/or a direction substantially perpendicular to the front surface FS1 of the display apparatus 1. In an embodiment, light emitted by the sub-pixel P may travel in a direction (e.g., a direction intersecting the z direction) oblique to the front surface FS1 of the display apparatus 1.

In an embodiment, the sub-pixel P may emit red light, green light, or blue light by using a display element. In an embodiment, the sub-pixel P may emit red light, green light, blue light, or white light by using a display element. In an embodiment, the sub-pixel P may be defined as an emission area of a display element that emits light of a color from among red, green, blue, and white. In this case, a plurality of sub-pixels P may be provided, and the plurality of sub-pixels P may be spaced apart from each other. Also, some of the plurality of sub-pixels P, and others of the plurality of sub-pixels P may emit light of different colors.

The sub-pixel P may include a light-emitting diode as a display element capable of emitting light of a certain color. The light-emitting diode may include an organic light-emitting diode including an organic material as an emission layer. Alternatively, the light-emitting diode may include an inorganic light-emitting diode. Alternatively, the light-emitting diode may include quantum dots as an emission layer. In an embodiment, the light-emitting diode may have a micro-scale or nano-scale size. For example, the light-emitting diode may be a micro light-emitting diode. Alternatively, the light-emitting diode may be a nano light-emitting diode. For convenience of explanation, the following will be described assuming that the light-emitting diode includes an organic light-emitting diode.

The peripheral area PA may be an area where an image is not displayed. The peripheral area PA may at least partially surround the display area DA. In an embodiment, the peripheral area PA may entirely surround the display area DA. A driver or the like for applying an electrical signal or power to the sub-pixel P may be located in the peripheral area PA. Also, the peripheral area PA may include a pad area where a plurality of pads are located.

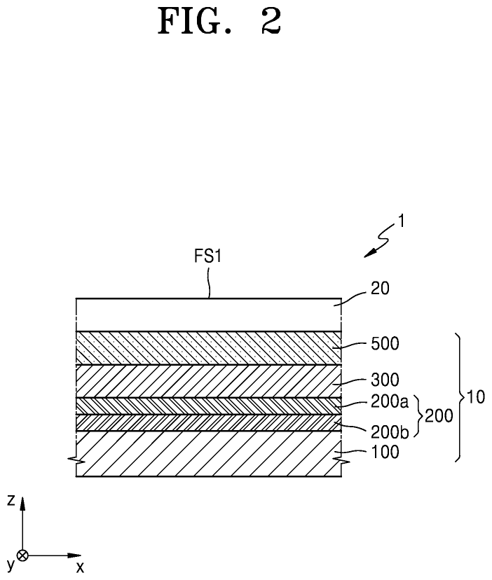

FIG. 2 is a cross-sectional view schematically illustrating the display apparatus according to an embodiment.

Referring to FIG. 2, the display apparatus 1 may include a display panel 10 and a cover window 20. The display panel 10 may include a substrate 100, a display layer 200, an encapsulation layer 300, and an optical layer 500.

The substrate 100 may include glass or polymer resin such as polyethersulfone, polyarylate, polyetherimide, polyethylene naphthalate, polyethylene terephthalate, polyphenylene sulfide, polyimide, polycarbonate, cellulose triacetate, or cellulose acetate propionate. In an embodiment, the substrate 100 may have a multi-layer structure including a base layer including the polymer resin and a barrier layer (not shown). The substrate 100 including the polymer resin may be flexible, rollable, or bendable.

The display layer 200 may be located on the substrate 100. The display layer 200 may include a display element layer 200a and a pixel circuit layer 200b. The pixel circuit layer 200b may include pixel circuits. The display element layer 200a may include a plurality of display elements respectively connected to a plurality of pixel circuits. Each of the display elements provided in the display element layer 200a may define a pixel. The pixel circuit layer 200b may include a plurality of thin-film transistors and at least one storage capacitor.

The encapsulation layer 300 may be located on the display layer 200. In an embodiment, the encapsulation layer 300 may include at least one inorganic encapsulation layer and at least one organic encapsulation layer. The at least one inorganic encapsulation layer may include at least one inorganic material from among aluminum oxide (Al₂O₃), titanium oxide (TiO₂), tantalum oxide (Ta₂O₅), zinc oxide (ZnOₓ, which may be ZnO and/or ZnO₂), silicon oxide (SiO₂), silicon nitride (SiNₓ), and silicon oxynitride (SiON). The at least one organic encapsulation layer may include a polymer-based material. Examples of the polymer-based material may include an acrylic resin, an epoxy resin, polyimide, and polyethylene. In an embodiment, the at least one organic encapsulation layer may include acrylate.

The optical layer 500 may be located on the encapsulation layer 300. The optical layer 500 may include a light-blocking layer. In this case, the light-blocking layer may at least partially absorb external light or internally reflected light. The light-blocking layer may include a black pigment. The light-blocking layer may be a black matrix. The light-blocking layer may be located in the display area DA. The light-blocking layer may include an opening through which light emitted from a pixel located in the display are DA passes to the outside.

In an embodiment, the optical layer 500 may include a light-blocking layer and a color filter layer. In this case, the light-blocking layer may include an opening through which light emitted from the pixel passes as described above, and the color filter layer may be located in the opening of the light-blocking layer.

The cover window 20 may be located on the display panel 10. In an embodiment, the cover window 20 may be coupled to an element under the cover window 20, for example, the optical layer 500, through an adhesive such as an optically clear adhesive (OCA). The cover window 20 may protect the display panel 10. The cover window 20 may include at least one of glass, sapphire, and plastic. The cover window 20 may include, for example, ultra-thin glass (UTG) or colorless polyimide (CPI).

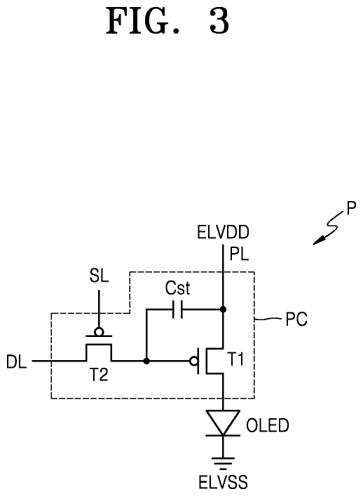

FIG. 3 is an equivalent circuit diagram schematically illustrating a sub-pixel included in a display apparatus, according to an embodiment.

Referring to FIG. 3, the sub-pixel P may include a pixel circuit PC and an organic light-emitting diode OLED as a display element.

The pixel circuit PC may include a driving thin-film transistor T1, a switching thin-film transistor T2, and a storage capacitor Cst. Each sub-pixel P may emit, for example, red light, green light, or blue light, or may emit red light, green light, blue light, or white light through the organic light-emitting diode OLED.

The switching thin-film transistor T2 may be connected to a scan line SL and a data line DL, and may transmit a data signal or a data voltage input from the data line DL to the driving thin-film transistor T1 in response to a scan signal or a switching voltage input from the scan line SL. The storage capacitor Cst may be connected to the switching thin-film transistor T2 and a driving voltage line PL, and may store a voltage corresponding to a difference between a voltage received from the switching thin-film transistor T2 and a first power supply voltage ELVDD supplied to the driving voltage line PL.

The driving thin-film transistor T1 may be connected between the driving voltage line PL and the organic light-emitting diode OLED, and may control driving current flowing from the driving voltage line PL to the organic light-emitting diode OLED in response to a value of the voltage stored in the storage capacitor Cst. The organic light-emitting diode OLED may emit light having a certain luminance according to the driving current. A counter electrode (e.g., a cathode) of the organic light-emitting diode OLED may receive a second power supply voltage ELVSS.

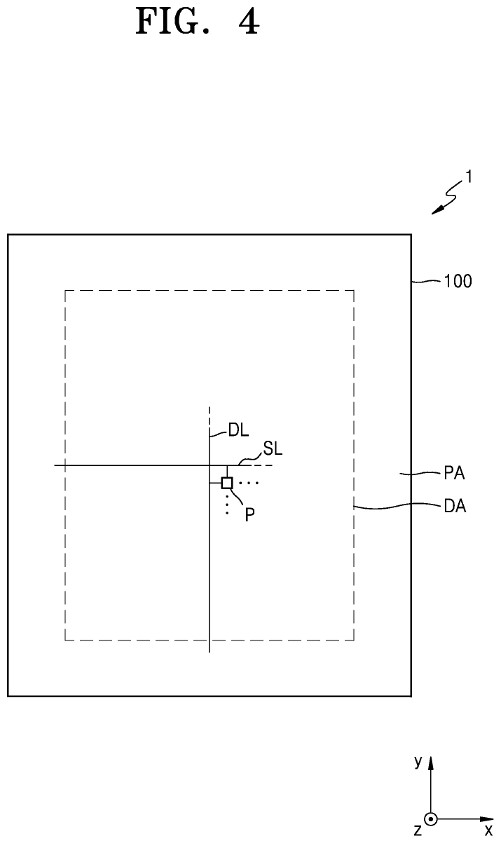

FIG. 4 is a plan view schematically illustrating a display apparatus according to an embodiment.

Referring to FIG. 4, the display apparatus 1 may include the substrate 100 and multiple layers located on the substrate 100. The display area DA and the peripheral area PA may be defined on the substrate 100. For example, the substrate 100 may include the display area DA and the peripheral area PA. The following will be described assuming that the display area DA and the peripheral area PA are defined on the substrate 100.

The sub-pixel P may be located in the display area DA, and a plurality of sub-pixels P may display an image. Each of the sub-pixels P may be connected to the scan line SL extending in a first direction (e.g., an x direction or a −x direction) and the data line DL extending in a second direction (e.g., a y direction or a −y direction).

The peripheral area PA may be located outside the display area DA. The peripheral area PA may at least partially surround the display area DA. In an embodiment, the peripheral area PA may entirely surround the display area DA. A scan driver (not shown) for applying a scan signal to each sub-pixel P may be located in the peripheral area PA. A data driver for applying a data signal to the sub-pixel P may be located in the peripheral area PA. The peripheral area PA may include a pad area (not shown). In an embodiment, a plurality of pads (not shown) may be located in the pad area. The plurality of pads may be exposed by pad openings in an insulating layer, and may be electrically connected to a printed circuit board or a driver integrated circuit (IC) through the pad openings. Signals and/or voltages received from the printed circuit board or the driver IC through the plurality of pads may be transmitted to the sub-pixel P located in the display area DA through a wiring (not shown) connected to the plurality of pads.

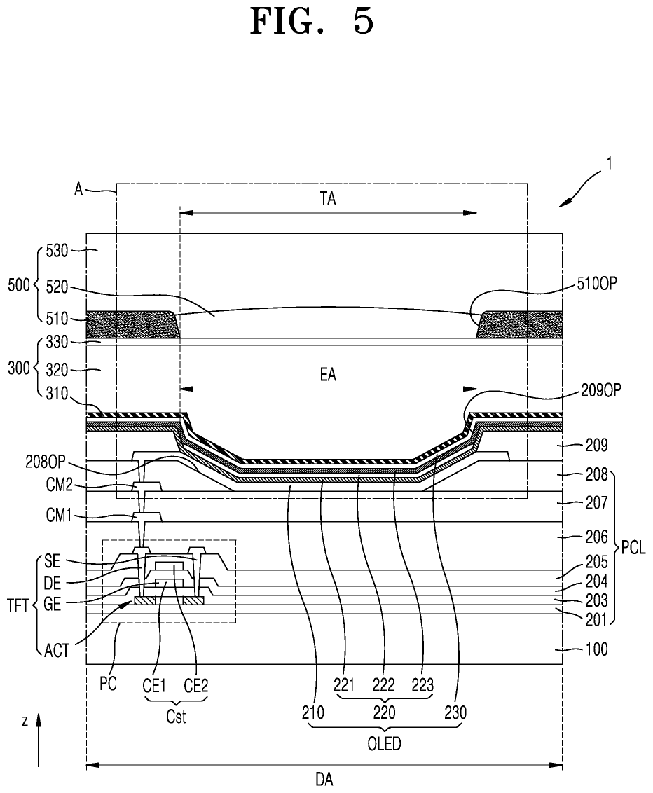

FIG. 5 is a cross-sectional view schematically illustrating a display apparatus according to an embodiment.

Referring to FIG. 5, the display apparatus 1 may include the substrate 100, the pixel circuit layer PCL, the organic light-emitting diode OLED, the encapsulation layer 300, and the optical layer 500, and a cover window (not shown), as shown in FIG. 2.

The display apparatus 1 may include the display area DA.

The substrate 100 may include glass or a polymer resin such as polyethersulfone, polyarylate, polyetherimide, polyethylene naphthalate, polyethylene terephthalate, polyphenylene sulfide, polyimide, polycarbonate, cellulose triacetate, or cellulose acetate propionate. In an embodiment, the substrate 100 may have a multi-layer structure including a base layer including the polymer resin and a barrier layer (not shown). The substrate 100 including the polymer resin may be flexible, rollable, or bendable.

The pixel circuit layer PCL may be located on the substrate 100.

The pixel circuit layer PCL may include a buffer layer 201, a first gate insulating layer 203, a second gate insulating layer 204, an interlayer insulating layer 205, a first planarization layer 206, a second planarization layer 207, and a first bank layer 208. A pixel circuit PC may include a thin-film transistor TFT and a storage capacitor Cst. The thin-film transistor TFT may include a semiconductor layer ACT, a gate electrode GE, a source electrode SE, and a drain electrode DE.

The buffer layer 201 may be located on the substrate 100. The buffer layer 201 may include an inorganic insulating material such as silicon nitride (SiNₓ), silicon oxynitride (SiON), or silicon oxide (SiO₂), and may have a single or multi-layer structure including the inorganic insulating material.

The thin-film transistor TFT may include the semiconductor layer ACT, and the semiconductor layer Act may be located on the buffer layer 201. The semiconductor layer ACT may include polysilicon. Alternatively, the semiconductor layer ACT may include amorphous silicon, an oxide semiconductor, or an organic semiconductor. The semiconductor layer ACT may include a channel region and a drain region and a source region located on opposite sides of the channel region, respectively.

A gate electrode GE may overlap the channel region. The gate electrode GE may include a low-resistance metal material. The gate electrode GE may include a conductive material including molybdenum (Mo), aluminum (Al), copper (Cu), or titanium (Ti), and may have a single or multi-layer structure including the above material.

The first gate insulating layer 203 between the semiconductor layer ACT and the gate electrode GE may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ, which may be ZnO and/or ZnO₂).

The second gate insulating layer 204 may cover the gate electrode GE. The second gate insulating layer 204 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ, which may be ZnO and/or ZnO₂), like the first gate insulating layer 203.

An upper electrode CE2 of the storage capacitor Cst may be located on the second gate insulating layer 204. The upper electrode CE2 may overlap the gate electrode GE that is located below the upper electrode CE2. In this case, the gate electrode GE and the upper electrode CE2 overlapping each other with the second gate insulating layer 204 disposed therebetween may constitute the storage capacitor Cst. That is, the gate electrode GE may function as a lower electrode CE1 of the storage capacitor Cst.

In an embodiment, the storage capacitor Cst and the thin-film transistor TFT may overlap each other.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single or multi-layer structure including the above material.

The interlayer insulating layer 205 may cover the upper electrode CE2. The interlayer insulating layer 205 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ, which may be ZnO and/or ZnO₂). The interlayer insulating layer 205 may have a single or multi-layer structure including the above inorganic insulating material.

Each of the drain electrode DE and the source electrode SE may be located on the interlayer insulating layer 205. Each of the drain electrode DE and the source electrode SE may include a material having excellent conductivity. Each of the drain electrode DE and the source electrode SE may include a conductive material including molybdenum (Mo), aluminum (Al), copper (Cu), or titanium (Ti), and may have a single or multi-layer structure including the above material. In an embodiment, each of the drain electrode DE and the source electrode SE may have a multi-layer structure including Ti/Al/Ti.

The first planarization layer 206 may cover the drain electrode DE and the source electrode SE. The first planarization layer 206 may include an organic insulating material such as a general-purpose polymer (e.g., polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

A first connection electrode CM1 may be located on the first planarization layer 206. The first connection electrode CM1 may be connected to the drain electrode DE through a contact hole formed through the first planarization layer 206. The first connection electrode CM1 may include a conductive material including Mo, Al, Cu, or Ti, and may have a single or multi-layer structure including the above material.

The second planarization layer 207 may cover the first connection electrode CM1. The second planarization layer 207 may include an organic insulating material such as a general-purpose polymer (e.g., polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

A second connection electrode CM2 may be located on the second planarization layer 207. The second connection electrode CM2 may be connected to the first connection electrode CM1, through a contact hole formed through the second planarization layer 207. The second connection electrode CM2 may include a conductive material including Mo, Al, Cu, or Ti, and may have a single or multi-layer structure including the above material.

The first bank layer 208 may cover the second connection electrode CM2. The first bank layer 208 may define a first opening 208OP formed through the first bank layer 208. A side surface of the first bank layer 208 defining the first opening 208OP may have an inclined surface. A bottom of the first opening 208OP may expose a top surface of the second planarization layer 207.

The display element layer may be located on the pixel circuit layer PCL. The display element layer may be located on the second planarization layer 207 and the first bank layer 208. The display element layer may include an organic light-emitting diode OLED as a display element and a second bank layer 209.

The organic light-emitting diode OLED may be located on the second planarization layer 207 and the first bank layer 208. The organic light-emitting diode OLED may emit red light, green light, or blue light, or may emit red light, green light, blue light, or white light.

The organic light-emitting diode OLED may include a pixel electrode 210, an intermediate layer 220, and a counter electrode 230.

The pixel electrode 210 may be located on the substrate 100. The pixel electrode 210 may be located on the second planarization layer 207 and the first bank layer 208. For example, the pixel electrode 210 may be located to extend from a top surface of the first bank layer 208 through the side surface of the first bank layer 208 defining the first opening 208OP to the top surface of the second planarization layer 207. The pixel electrode 210 may include an inclined surface located on the side surface of the first bank layer 208 and flat surfaces respectively located on an upper surface of the second planarization layer 207 and an upper surface of the first bank layer 208 having a flat surface.

The pixel electrode 210 may be electrically connected to the second connection electrode CM2 through a contact hole formed through the first bank layer 208. The pixel electrode 210 may be electrically connected to the thin-film transistor TFT through the second connection electrode CM2 and the first connection electrode CM1. The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). Alternatively, the pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 210 may further include a film formed of ITO, IZO, ZnO, or In₂O₃ over/under the above reflective film. For example, the pixel electrode 210 may have a multi-layer structure including ITO/Ag/ITO.

The second bank layer 209 may cover an edge of the pixel electrode 210. The second bank layer 209 may define a pixel opening 209OP overlapping the first opening 208OP. The pixel opening 209OP may expose a central portion of the pixel electrode 210. The pixel opening 209OP may define an emission area EA of the organic light-emitting diode OLED. The emission area EA is an area where the intermediate layer 220 contacts the pixel electrode 210 to emit light.

The intermediate layer 220 may include a first functional layer 221, an emission layer 222, and a second functional layer 223. The emission layer 222 may include a high molecular weight organic material or a low molecular weight organic material that emits light of a certain color.

In an embodiment, at least one of the first functional layer 221 and the second functional layer 223 may be a common layer entirely located in the display area DA. The first functional layer 221 may include, for example, a hole transport layer (HTL), or may include an HTL and a hole injection layer (HIL). The second functional layer 223 may include an electron transport layer (ETL) and/or an electron injection layer (EIL). The first functional layer 221 or the second functional layer 223 may be omitted.

The counter electrode 230 may be located on the intermediate layer 220. The counter electrode 230 may be formed of a conductive material having a low work function. For example, the counter electrode 230 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the counter electrode 230 may further include a layer formed of ITO, IZO, ZnO, or In₂O₃ on the (semi-)transparent layer including the above material.

In some embodiments, a capping layer (not shown) may be further located on the counter electrode 230. The capping layer may include an inorganic material (e.g., lithium fluoride (LiF)), and/or an organic material.

The encapsulation layer 300 may be located on the display element layer. The encapsulation layer 300 may cover the organic light-emitting diode OLED. In an embodiment, the encapsulation layer 300 may include at least one inorganic encapsulation layer and at least one organic encapsulation layer. In this regard, in FIG. 5, the encapsulation layer 300 includes a first inorganic encapsulation layer 310, an organic encapsulation layer 320, and a second inorganic encapsulation layer 330 which are sequentially stacked.

The at least one inorganic encapsulation layer may include at least one inorganic material from among aluminum oxide (Al₂O₃), titanium oxide (TiO₂), tantalum oxide (Ta₂O₅), hafnium oxide (HfO₂), zinc oxide (ZnOₓ, which may be ZnO and/or ZnO₂), silicon oxide (SiO₂), silicon nitride (SiNₓ), and silicon oxynitride (SiON).

The at least one organic encapsulation layer may include a polymer-based material. Examples of the polymer-based material may include an acrylic resin, an epoxy resin, polyimide, and polyethylene. In an embodiment, the at least one organic encapsulation layer may include acrylate.

The optical layer 500 may be located on the encapsulation layer 300. The optical layer 500 may include a light-blocking layer 510, a color filter layer 520, and an overcoat layer 530.

The light-blocking layer 510 may be located on the second inorganic encapsulation layer 330. The light-blocking layer 510 may define a second opening 510OP overlapping the pixel opening 209OP and formed through the light-blocking layer 510. The second opening 510OP may define a transmissive area TA through which light emitted by the organic light-emitting diode OLED is transmitted to the outside of the display apparatus 1.

In an embodiment, a width of the second opening 510OP of the light-blocking layer 510 may be substantially the same as a width of the pixel opening 209OP of the second bank layer 209 within an error margin. In other words, a width (or area) of the transmissive area TA may be substantially the same as a width (or area) of the emission area EA within an error margin. It is found through simulation that as a width of the second opening 510OP decreases, a reflectance of the display apparatus 1 is improved by 0.2%.

The light-blocking layer 510 may at least partially absorb external light or internally reflected light. The light-blocking layer 510 may include a black pigment. The light-blocking layer 510 may be a black matrix.

The color filter layer 520 may be located on the organic light-emitting diode OLED as the display element to correspond to the second opening 510OP of the light-blocking layer 510. In an embodiment, the color filter layer 520 may be located in the second opening 510OP of the light-blocking layer 510. The color filter layer 520 may be located on the second inorganic encapsulation layer 330 to fill the second opening 510OP. At least a part of the color filter layer 520 may overlap the emission layer 222. The color filter layer 520 may have a color corresponding to light emitted from the emission layer EA. For example, when red light is emitted from the emission area EA, the color filter layer 520 may be a red color filter. The color filter layer 520 may improve light efficiency extracted from the front of the display apparatus 1, thereby ensuring a lifespan of the display apparatus 1. The color filter layer 520 may include a pigment or a dye. In another embodiment, the color filter layer 520 may be a light-transmitting layer including a transparent photosensitive resin.

The overcoat layer 530 may be located on the color filter layer 520. The overcoat layer 530 is a light-transmitting layer that does not have a color in a visible band, and may provide a flat top surface and may cover an uneven portion generated when the color filter layer 520 and the light-blocking layer 510 are formed.

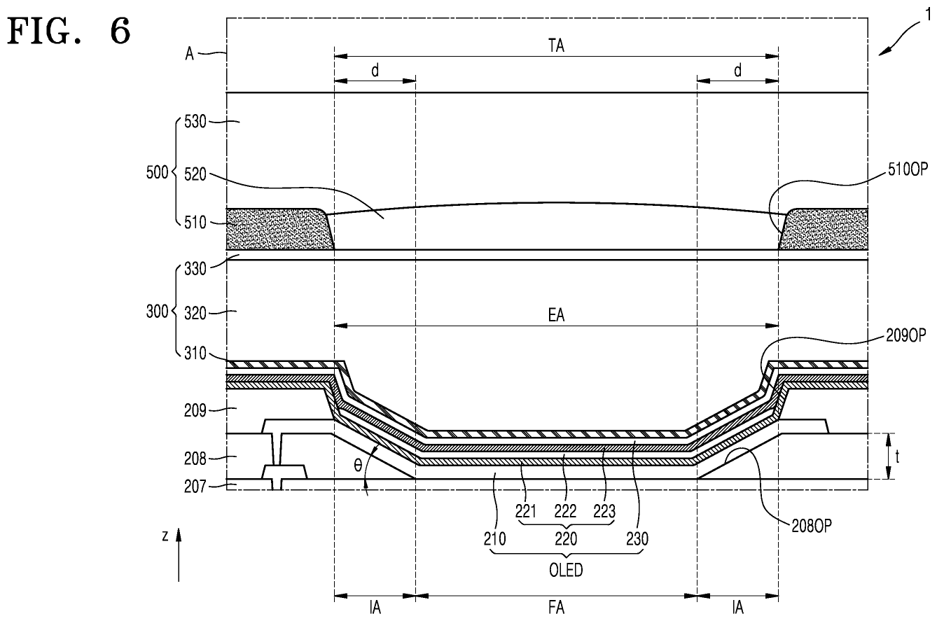

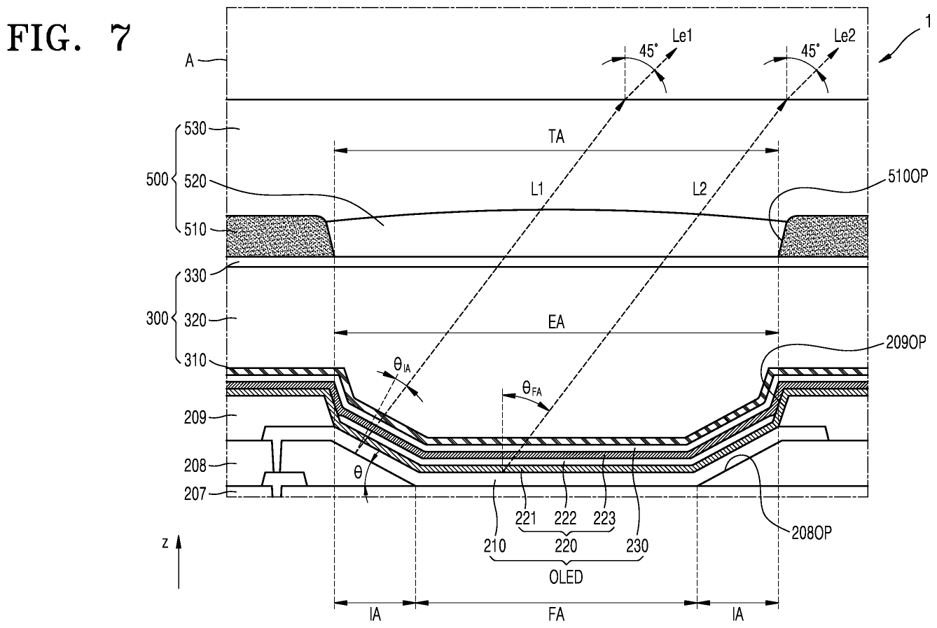

FIGS. 6 and 7 are enlarged cross-sectional views illustrating a portion A of the display apparatus of FIG. 5.

Referring to FIG. 6, the first bank layer 208 may be located on the second planarization layer 207. The first bank layer 208 may define the first opening 208OP. A side surface of the first bank layer 208 defining the first opening 208OP may have an inclined surface. A bottom surface of the first opening 208OP may be a top surface of the second planarization layer 207.

The organic light-emitting diode OLED may be located on the second planarization layer 207 and the first bank layer 208. The organic light-emitting diode OLED may include the pixel electrode 210, the intermediate layer 220, and the counter electrode 230.

The pixel electrode 210 may be located on the second planarization layer 207 and the first bank layer 208. For example, the pixel electrode 210 may be located to extend from a top surface of the first bank layer 208 through the side surface of the first bank layer 208 defining the first opening 208OP to the top surface of the second planarization layer 207. The pixel electrode 210 may include an inclined surface located on the side surface of the first bank layer 208 and flat surfaces respectively located on an upper surface of the second planarization layer 207 and an upper surface of the first bank layer 208 having a flat surface.

The second bank layer 209 may cover an edge of the pixel electrode 210. The second bank layer 209 may define the pixel opening 209OP overlapping the first opening 208OP. The pixel opening 209OP may expose a central portion of the pixel electrode 210. The pixel electrode 209OP may define the emission area EA of the organic light-emitting diode OLED. The emission area EA is an area where the intermediate layer 220 contacts the pixel electrode 210 to emit light.

The intermediate layer 220 may include the first functional layer 221, the emission layer 222, and the second functional layer 223. The emission layer 222 may include a high molecular weight organic material or a low molecular weight organic material that emits light of a certain color. The counter electrode 230 may be located on the intermediate layer 220.

The emission area EA may include an inclined area IA overlapping the inclined surface of the pixel electrode 210 and a flat area FA overlapping the flat surface of the pixel electrode 210. In other words, the pixel electrode 210 in the inclined area IA may be located on the inclined side surface of the first bank layer 208. The pixel electrode 210 in the flat area FA may be located on the top surface of the second planarization layer 207 exposed through the first opening 208OP. The inclined area IA may surround the flat area FA.

The inclined side surface of the first bank layer 208 may be inclined by a first angle θ from a top surface of the substrate 100. The first angle θ may range from about 15° to about 25°. Accordingly, the inclined surface of the pixel electrode 210 may be inclined by about 15° to about 25° with respect to the flat surface of the pixel electrode 210. The pixel electrode 210 may have a substantially concave shape. A thickness t of the first bank layer 208 may range from about 0.5 μm to about 2.3 μm.

A width of the inclined area IA may range from about 1 μm to about 5 μm. In other words, in a plan view, a first distance d between an (outer) boundary of the inclined surface of the pixel electrode 210 and a boundary of the flat surface of the pixel electrode 210 may range from about 1 μm to about 5 μm.

The encapsulation layer 300 may be located on the counter electrode 230. The encapsulation layer 300 may include the first inorganic encapsulation layer 310, the organic encapsulation layer 320, and the second inorganic encapsulation layer 330 which are sequentially stacked.

The optical layer 500 may be located on the encapsulation layer 300. The optical layer 500 may include the light-blocking layer 510, the color filter layer 520, and the overcoat layer 530.

The light-blocking layer 510 may be located on the second inorganic encapsulation layer 330. The light-blocking layer 510 may define the second opening 510OP overlapping the pixel opening 209OP and formed through the light-blocking layer 510. The second opening 510OP may define the transmissive area TA through which light emitted from the organic light-emitting diode OLED is transmitted to the outside of the display apparatus 1.

In an embodiment, a width of the second opening 510OP of the light-blocking layer 510 may be substantially the same as a width of the pixel opening 209OP of the second bank layer 209 within an error margin. In other words, a width (or area) of the transmissive area TA may be substantially the same as a width (or area) of the emission area EA within an error margin. In other words, in a plan view, a distance between a boundary of the flat surface of the pixel electrode 210 and a boundary of the second opening 510OP may be substantially the same as the first distance d.

The color filter layer 520 may be located in the second opening 510OP of the light-blocking layer 510. The overcoat layer 530 may be located on the color filter layer 520.

Referring to FIG. 7, the emission area EA may include the inclined area IA overlapping the inclined surface of the pixel electrode 210 and the flat area FA overlapping the flat surface of the pixel electrode 210.

First emission light Le1 and second emission light Le2 is defined as light traveling along paths inclined by about 45° with reference to a direction perpendicular to a top surface of the display apparatus 1. The first emission light Le1 may be obtained when first light L1 emitted from the inclined area IA is refracted from an uppermost surface of the display apparatus 1 such as the overcoat layer 530 or a cover window (not shown). The second emission light Le2 may be obtained when second light L2 emitted from the flat area FA is refracted from an uppermost surface of the display apparatus 1 such as the overcoat layer 530 or the cover window (not shown).

In an embodiment, when a first angle θ between an inclined surface of the first bank layer 208 and a top surface of the substrate 100 is about 20°, an emission angle θ_{IA} of the first light L1 between a direction perpendicular to an inclined surface of the pixel electrode 210 and a direction of the first light L1 emitted from the inclined area IA may be about 8.2°. On the other hand, an emission angle θ_{FA} of the second light L2 between a direction perpendicular to a flat surface of the pixel electrode 210 and a direction of the second light L2 emitted from the flat area FA may be about 28.2°.

A display apparatus including an organic light-emitting diode has a highest luminance when viewed in a direction perpendicular to a substrate. As a viewing angle increases, a luminance decreases, and when a viewing angle is about 20° or more, a luminance may greatly decrease. The term “viewing angle” used herein refers to an angle formed by a line perpendicular to a front surface of a display apparatus and a line a user views the display apparatus. Also, a luminance decrease according to a viewing angle for each sub-pixel may vary depending on a color of light emitted by an organic light-emitting diode of each sub-pixel. Accordingly, when a viewing angle changes, white color coordinates of a display apparatus may change, thereby degrading the color of the display apparatus.

Accordingly, in the display apparatus 1 according to embodiments, because the inclined surface of the pixel electrode 210 is inclined by about 20° with respect to the flat surface of the pixel electrode 210, a luminance decrease of the display apparatus 1 at a high viewing angle may be reduced or prevented. Also, the display apparatus 1 may have color coordinates similar to reference white color coordinates at a high viewing angle.

Considering an error in a process of the first bank layer 208 including an organic insulating layer, a side surface of the first bank layer 208 defining the first opening 208OP may be inclined by about 15° to about 25°. Accordingly, the inclined surface of the pixel electrode 210 may also be inclined by about 15° to about 25° with respect to the flat surface of the pixel electrode 210.

In this case, as a first distance, which is a width of the inclined area IA, between an (outer) boundary of the inclined surface of the pixel electrode 210 and a boundary of the flat surface of the pixel electrode 210 increases, a white angle difference (WAD) of the display apparatus 1 may decrease, but power consumption may increase as the area of the emission area EA where the pixel electrode 210 and the intermediate layer 220 contact each other increases.

Table 1 is a table showing a power consumption increase rate of the display apparatus 1, when the first angle θ and the first distance d change.

TABLE 1

Power consumption increase rate according
to first distance (d)

| First angle (θ) | 1 μm | 2 μm | 5 μm |
|---|---|---|---|
| 15° | 0.7% | 1.3% | 2.74% |
| 20° | 1.14% | 2.14% | 4.54% |
| 30° | 2.57% | 4.91% | 10.74% |
| 45° | 5.82% | 11.43% | 26.91% |
| 60° | 8.14% | 16.31% | 40.81% |

The first distance d may be less than about 5 μm, so that the power consumption increase rate is 5% or less. For example, considering an error in a process of the first bank layer 208 including an organic insulating material, the first distance may range from about 1 μm to about 5 μm. A thickness of the first bank layer 208 may range from about 0.5 μm to about 2.3 μm.

Also, because light emitted from the inclined area IA travels along a path oblique to a direction perpendicular to the substrate 100, even when the transmissive area TA has substantially the same width (or area) as the emission area EA, side visibility of the display apparatus 1 may be ensured.

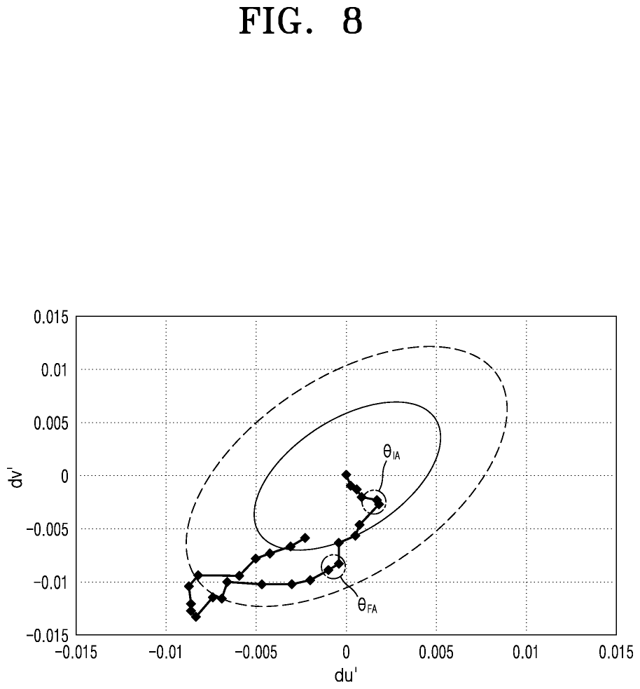

FIG. 8 is a graph illustrating a change in white color coordinates of a conventional display apparatus according to a change in a viewing angle. FIG. 8 is a graph illustrating a result obtained by measuring white color coordinates of a conventional display apparatus while changing a viewing angle by every 2°. A pixel electrode of each of organic light-emitting diodes of the conventional display apparatus has only a flat surface without an inclined surface. In the graph, du′ means the amount of variation of the u value of the CIE color coordinate system, and dv′ means the amount of variation of the v value.

Referring to FIG. 8, it is found that when a viewing angle changes by less than 20°, measured values of white color coordinates of the display apparatus are located within a reference range (within a solid line range). However, when a viewing angle is about 20° or more, a luminance of a red pixel rapidly decreases and measured values of white color coordinates move to a blue region which is disposed outside of the reference range (outside of the solid line range).

As described with reference to FIG. 7, the first emission light Le1 having a viewing angle of 45° with respect to a direction perpendicular to a front surface of the display apparatus 1 according to embodiments may be obtained when the first light L1 emitted from the inclined area IA is refracted. In this case, the emission angle θ_{IA} of the first light L1 may be about 8.2°. Because the emission angle θ_{IA} is about 8.2° or less, the first emission light Le1 may have white color coordinates within the reference range. The second emission light Le2 may be obtained when the second light L2 emitted from the flat area FA is refracted, and the emission angle θ_{FA} of the second light L2 may be about 28.2°. Although the second emission light Le2 has white color coordinates outside the reference range, the first emission light Le1 and the second emission light Le2 may be mixed to improve the color of the display apparatus 1.

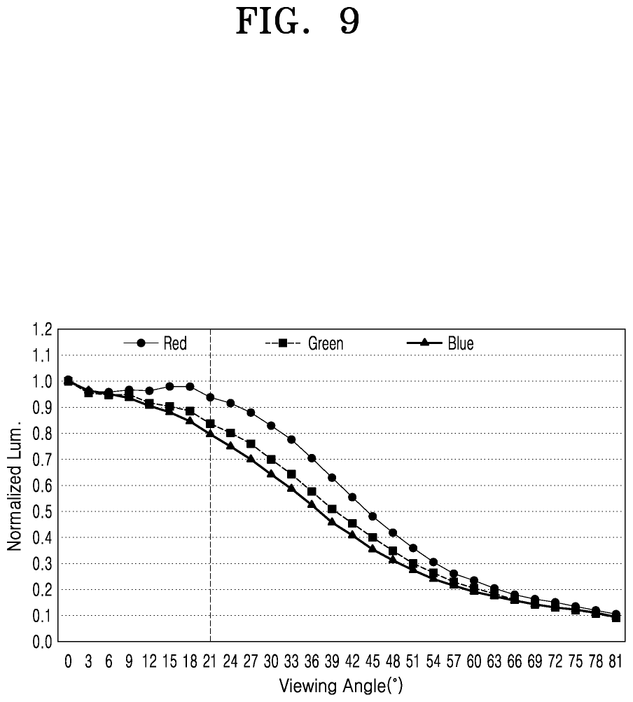

FIG. 9 is a graph illustrating a change in a luminance of sub-pixels according to a change in a viewing angle in which a pixel electrode has only a flat surface. FIG. 9 illustrates a result obtained by measuring normalized luminance of each of sub-pixels while changing a viewing angle by every 3°.

Referring to FIG. 9, it is found that, as a viewing angle increases, a luminance of each of a red sub-pixel Red, a green sub-pixel Green, and a blue sub-pixel Blue decreases. Because a luminance decrease varies according to a color of light emitted by each sub-pixel, the color of a display apparatus may vary according to a viewing angle.

In the case of the red sub-pixel Red, when a viewing angle changes from 0° to 21°, a luminance decreases by about 10%. Accordingly, it is found that, in the case of the green sub-pixel Green and the blue sub-pixel Blue, when a viewing angle changes from 0° to 21°, a luminance decreases by about 20%.

In the display apparatus 1 (see FIG. 7) according to an embodiment, considering an error margin in a process of the first bank layer 208 (see FIG. 7) including an organic insulating material, a side surface of the first bank layer 208 (see FIG. 7) defining the first opening 208OP (see FIG. 7) may be inclined by about 15° to about 25°. An inclined surface of the pixel electrode 210 (see FIG. 7) may be inclined by about 15° to about 25° with respect to a flat surface of the pixel electrode 210 (see FIG. 7). In this case, when light emitted from the inclined area IA of the organic light-emitting diode OLED (see FIG. 7) is emitted in a direction perpendicular to a front surface of the display apparatus 1 (see FIG. 7), a luminance decrease may be limited to within about 10% to about 20%. Accordingly, even when the pixel electrode 210 (see FIG. 7) has the inclined surface, an overall power consumption increase rate for maintaining a constant front luminance of the display apparatus 1 (see FIG. 7) may be reduced to less than about 5%.

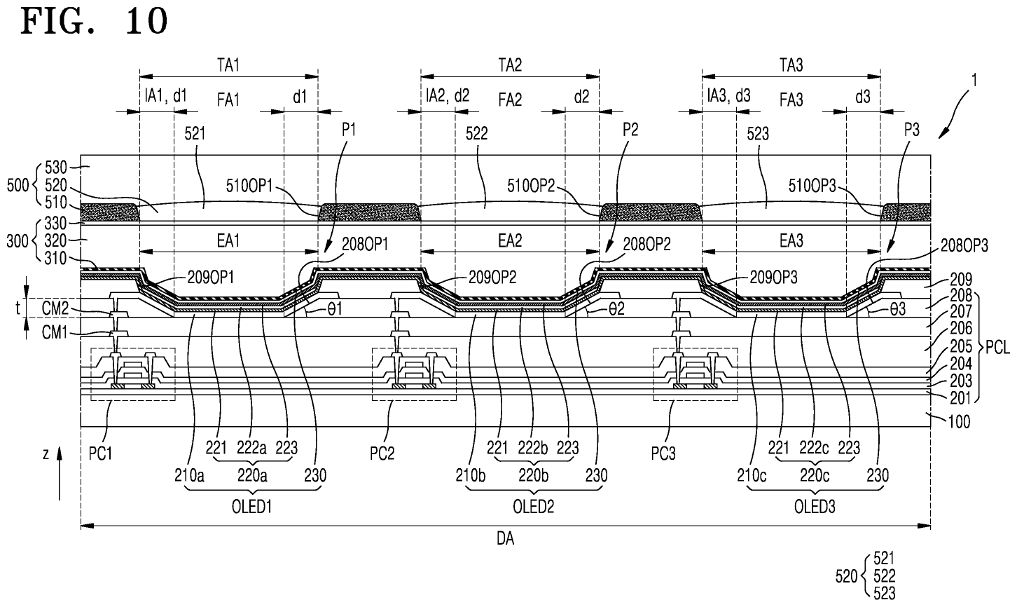

FIG. 10 is a cross-sectional view schematically illustrating a display apparatus according to an embodiment.

Referring to FIG. 10, the display apparatus 1 may include the display area DA. In the display area DA, a first sub-pixel P1, a second sub-pixel P2, and a third pixel P3 may be disposed to be spaced apart from each other. The first sub-pixel P1 may include a first organic light-emitting diode OLED1 as a display element and a first pixel circuit PC1 electrically connected to the first organic light-emitting diode OLED1. The second sub-pixel P2 may include a second organic light-emitting diode OLED2 and a second pixel circuit PC2 electrically connected to a second organic light-emitting diode OLED2. The third sub-pixel P3 may include a third organic light-emitting diode OLED3 and a third pixel circuit PC3 electrically connected to the third organic light-emitting diode OLED3.

The pixel circuit layer PCL may be located on the substrate 100. The pixel circuit layer PCL may include the buffer layer 201, the first gate insulating layer 203, the second gate insulating layer 204, the interlayer insulating layer 205, the first planarization layer 206, the second planarization layer 207, and the first bank layer 208.

The pixel circuit layer PCL may include the first pixel circuit PC1, the second pixel circuit PC2, and the third pixel circuit PC3. Each of the first pixel circuit PC1, the second pixel circuit PC2, and the third pixel circuit PC3 may include at least one thin-film transistor and a storage capacitor. Each of the first pixel circuit PC1, the second pixel circuit PC2, and the third pixel circuit PC3 may have the same or similar configuration as the pixel circuit PC described with reference to FIG. 5.

The first planarization layer 206 may be located to cover a drain electrode and a source electrode of each of the first pixel circuit PC1, the second pixel circuit PC2, and the third pixel circuit PC3.

The first connection electrodes CM1 may be located on the first planarization layer 206. Each of the first connection electrode CM1 may be connected to the drain electrode of a corresponding pixel circuit through a contact hole formed through the first planarization layer 206.

The second planarization layer 207 may cover the first connection electrodes CM1.

The second connection electrodes CM2 may be located on the second planarization layer 207. Each of the second connection electrodes CM2 may be connected to a corresponding first connection electrode CM1, through a contact hole formed through the second planarization layer 207.

The first bank layer 208 may cover the second connection electrode CM2. The first bank layer 208 may define a 1-1^{th} opening 208OP1, a 1-2^{th} opening 2080P2, and a 1-3^{th} opening 208OP3 formed through the first bank layer 208 and spaced apart from each other. Side surfaces of the first bank layer 208 respectively defining the 1-1^{th} opening 208OP1, the 1-2^{th} opening 2080P2, and the 1-3^{th} opening 2080P3 may be inclined surfaces. For example, the side surface of the first bank layer 208 defining the 1-1^{th} opening 208OP1 may have a 1-1^{th} angle θ1, the side surface of the first bank layer 208 defining the 1-2^{th} opening 2080P2 may have a 1-2^{th} angle θ2, and the side surface of the first bank layer 208 defining the 1-3^{th} opening 2080P3 may have a 1-3^{th} angle θ3. The 1-1^{th} angle θ1, the 1-2^{th} angle θ2, and the 1-3^{th} angle θ3 may be different from each other. Alternatively, at least one of the 1-1^{th} angle θ1, the 1-2^{th} angle θ2, and the 1-3^{th} angle θ3 may be different from the other two angles. Each of the 1-1^{th} angle θ1, the 1-2^{th} angle θ2, a1^{th} and the 1-3^{th} angle θ3 may range from about 15° to about 25°. A thickness t of the first bank layer 208 may range from about 0.5 μm to about 2.3 μm.

The display element layer may be located on the pixel circuit layer PCL. The display element layer may be located on the second planarization layer 207 and the first bank layer 208. The display element layer may include the first organic light-emitting diode OLED1, the second organic light-emitting diode OLED2, and the third organic light-emitting diode OLED3 as display elements, and the second bank layer 209.

The first organic light-emitting diode OLED1, the second organic light-emitting diode OLED2, and the third organic light-emitting diode OLED3 may be located on the second planarization layer 207 and the first bank layer 208. The first organic light-emitting diode OLED1, the second organic light-emitting diode OLED2, and the third organic light-emitting diode OLED3 may emit light of different colors. For example, the first organic light-emitting diode OLED1 may emit red light, the second organic light-emitting diode OLED2 may emit green light, and the third organic light-emitting diode OLED3 may emit blue light. However, the disclosure is not limited thereto.

The first organic light-emitting diode OLED1 may include a first pixel electrode 210a, a first intermediate layer 220a, and the counter electrode 230, the second organic light-emitting diode OLED2 may include a second pixel electrode 210b, a second intermediate layer 220b, and the counter electrode 230, and the third organic light-emitting diode OLED3 may include a third pixel electrode 210c, a third intermediate layer 220c, and the counter electrode 230.

The first pixel electrode 210a may be located to correspond to the 1-1^{th} opening 208OP1. The first pixel electrode 210a may be located on the second planarization layer 207 and the first bank layer 208, and the first pixel electrode 210a may be located to extend from a top surface of the first bank layer 208, through the side surface of the first bank layer 208 defining the 1-1^{th} opening 208OP1, to a top surface of the second planarization layer 207 exposed through the 1-1^{th} opening 208OP1. Accordingly, the first pixel electrode 210a may include an inclined surface located on the side surface of the first bank layer 208 and a flat surface located on the second planarization layer 207. The inclined surface of the first pixel electrode 210a may be inclined by about 15° to about 25° with respect to the flat surface of the first pixel electrode 210a.

The second pixel electrode 210b may be located to correspond to the 1-2^{th} opening 2080P2. The second pixel electrode 210b may be located on the second planarization layer 207 and the first bank layer 208, and the second pixel electrode 210b may be located to extend from a top surface of the first bank layer 208, through the side surface of the first bank layer 208 defining the 1-2^{th} opening 2080P2, to a top surface of the second planarization layer 207 exposed through the 1-2^{th} opening 208OP2. Accordingly, the second pixel electrode 210b may include an inclined surface located on the side surface of the first bank layer 208 and a flat surface located on the second planarization layer 207. The inclined surface of the second pixel electrode 210b may be inclined by about 15° to about 25° with respect to the flat surface of the second pixel electrode 210b.

The third pixel electrode 210c may be located to correspond to the 1-3^{th} opening 208OP3. The third pixel electrode 210c may be located on the second planarization layer 207 and the first bank layer 208, and the third pixel electrode 210c may be located to extend from a top surface of the first bank layer 208, through the side surface of the first bank layer 208 defining the 1-3^{th} opening 2080P3, to a top surface of the second planarization layer 207 exposed through the 1-3^{th} opening 208OP3. Accordingly, the third pixel electrode 210c may include an inclined surface located on the side surface of the first bank layer 208 and a flat surface located on the second planarization layer 207. The inclined surface of the third pixel electrode 210c may be inclined by about 15° to about 25° with respect to the flat surface of the third pixel electrode 210c.

Each of the first pixel electrode 210a, the second pixel electrode 210b, and the third pixel electrode 210c may have a substantially concave shape.

The second bank layer 209 may cover edges of the first pixel electrode 210a, the second pixel electrode 210b, and the third pixel electrode 210c. The second bank layer 209 may define a first pixel opening 209OP1 overlapping the 1-1^{th} opening 208OP1, a second pixel opening 209OP2 overlapping the 1-2^{th} opening 2080P2, and a third pixel opening 209OP3 overlapping the 1-3^{th} opening 208OP3. The first pixel opening 209OP1 may expose a central portion of the first pixel electrode 210a, the second pixel opening 209OP2 may expose a central portion of the second pixel electrode 210b, and the third pixel opening 209OP3 may expose a central portion of the third pixel electrode 210c. The first pixel opening 209OP1 may define a first emission area EA1 of the first organic light-emitting diode OLED1, the second pixel opening 209OP2 may define a second emission area EA2 of the second organic light-emitting diode OLED2, and the third pixel opening 209OP3 may define a third emission area EA3 of the third organic light-emitting diode OLED3.

The first emission area EA1 may include a first inclined area IA1 overlapping the inclined surface of the first pixel electrode 210a and a first flat area FA1 overlapping the flat surface of the first pixel electrode 210a. The first inclined area IA1 may surround the first flat area FA1. A width of the first inclined area IA1 may range from about 1 μm to about 5 μm. In other words, in a plan view, a 1-1^{th} distance d1 between an (outer) boundary of the inclined surface of the first pixel electrode 210a and a boundary of the flat surface of the first pixel electrode 210a may range from about 1 μm to about 5 μm.

The second emission area EA2 may include a second inclined area IA2 overlapping the inclined surface of the second pixel electrode 210b and a second flat area FA2 overlapping the flat surface of the second pixel electrode 210b. A width of the second inclined area IA2 may range from about 1 μm to about 5 μm. In other words, in a plan view, a 1-2^{th} distance d2 between an (outer) boundary of the inclined surface of the second pixel electrode 210b and a boundary of the flat surface of the second pixel electrode 210b may range from about 1 μm to about 5 μm.

The third emission area EA3 may include a third inclined area IA3 overlapping the inclined surface of the third pixel electrode 210c and a third flat area FA3 overlapping the flat surface of the third pixel electrode 210c. A width of the third inclined area IA3 may range from about 1 μm to about 5 μm. In other words, in a plan view, a 1-3^{th} distance d3 between an (outer) boundary of the inclined surface of the third pixel electrode 210c and a boundary of the flat surface of the third pixel electrode 210c may range from about 1 μm to about 5 μm.

In an embodiment, the 1-1^{th} distance d1, the 1-2^{th} distance d2, and the 1-3^{th} distance d3 may be different from each other. In another embodiment, any one of the 1-1^{th} distance d1, the 1-2^{th} distance d2, and the 1-3^{th} distance d3 may be different from the other two distances. Because the 1-1^{th} distance d1, the 1-2^{th} distance d2, and the 1-3^{th} distance d3 are different from each other, a luminance of light emitted from each sub-pixel at a high viewing angle may be adjusted. Accordingly, the color of a display apparatus at a high viewing angle may be adjusted.

The first intermediate layer 220a may include the first functional layer 221, a first emission layer 222a, and the second functional layer 223. The second intermediate layer 220b may include the first functional layer 221, a second emission layer 222b, and the second functional layer 223. The third intermediate layer 220c may include the first functional layer 221, a third emission layer 222c, and the second functional layer 223. Each of the first emission layer 222a, the second emission layer 222b, and the third emission layer 222c may include a high molecular weight organic material or a low molecular weight organic material emitting light of a certain color. The first emission layer 222a may be located to correspond to the first pixel electrode 210a, the second emission layer 222b may be located to correspond to the second pixel electrode 210b, and the third emission layer 222c may be located to correspond to the third pixel electrode 210c. At least one of the first functional layer 221 and the second functional layer 223 may be a common layer entirely located in the display area DA over the first organic light-emitting diode OLED1, the second organic light-emitting diode OLED2, and the third organic light-emitting diode OLED3.

The counter electrode 230 may be located on the first intermediate layer 220a, the second intermediate layer 220b, and the third intermediate layer 220c. In some embodiments, a capping layer (not shown) may be further located on the counter electrode 230. The capping layer may include an inorganic material (e.g., LiF), and/or an organic material.

The encapsulation layer 300 may be located on the display element layer. The encapsulation layer 300 may cover the first organic light-emitting diode OLED1, the second organic light-emitting diode OLED2, and the third organic light-emitting diode OLED3. In an embodiment, the encapsulation layer 300 may include at least one inorganic encapsulation layer and at least one organic encapsulation layer. In this regard, in FIG. 10, the encapsulation layer 300 includes the first inorganic encapsulation layer 310, the organic encapsulation layer 320, and the second inorganic encapsulation layer 330 which are sequentially stacked.

The optical layer 500 may be located on the encapsulation layer 300. The optical layer 500 may include the light-blocking layer 510, the color filter layer 520, and the overcoat layer 530.

The light-blocking layer 510 may be located on the second inorganic encapsulation layer 330. The light-blocking layer 510 may define a 2-1^{th} opening 510OP1 overlapping the first pixel opening 209OP1, a 2-2^{th} opening 510OP2 overlapping the second pixel opening 209OP2, and a 2-3^{th} opening 510OP3 overlapping the third pixel opening 209OP3. The 2-1^{th} opening 510OP1 may define a first transmissive area TA1 through which light emitted by the first organic light-emitting diode OLED1 is transmitted to the outside of the display apparatus 1, the 2-2^{th} opening 510OP2 may define a second transmissive area TA2 through which light emitted by the second organic light-emitting diode OLED2 is transmitted to the outside of the display apparatus 1, and the 2-3^{th} opening 510OP3 may define a third transmissive area TA3 through which light emitted by the third organic light-emitting diode OLED3 is transmitted to the outside of the display apparatus 1.

In an embodiment, a width of the 2-1^{th} opening 510OP1 of the light-blocking layer 510 may be substantially the same as a width of the first pixel opening 209OP1 of the second bank layer 209 with an error margin, a width of the 2-2^{th} opening 510OP2 may be substantially the same as a width of the second pixel opening 209OP2 within an error margin, and a width of the 2-3^{th} opening 510OP3 may be substantially the same as a width of the third pixel opening 209OP3 within an error margin. In other words, a width (or area) of the first transmissive area TA1 may be substantially the same as a width (or area) of the first emission area EA1 within an error margin, a width (or area) of the second transmissive area TA2 may be substantially the same as a width of the second emission area EA2 within an error margin, and a width (or area) of the third transmissive area TA3 may be substantially the same as a width (or area) of the third emission area EA3 within an error margin.

In a comparative example, in a conventional display apparatus, considering WAD characteristics, a width (or area) of a transmissive area should be greater than a width (or area) of an emission area. Accordingly, there is a limitation in improving an aperture ratio of a pixel opening. However, in the display apparatus 1 according to an embodiment, because a width (or area) of a transmissive area may be substantially the same as a width (or area) of an emission area, an aperture ratio of a pixel opening may be greatly improved. Compared to the conventional display apparatus, an aperture ratio of a pixel opening of the display apparatus 1 according to an embodiment is improved by about 40%, and it is found through simulation that a lifespan is improved by about 30%. Also, as the area of the light-blocking layer 510 increases, a reflectance of the display apparatus 1 may be improved.

The light-blocking layer 510 may at least partially absorb external light or internally reflected light. The light-blocking layer 510 may include a black pigment. The light-blocking layer 510 may be a black matrix.

The color filter layer 520 may include a first color filter layer 521 corresponding to the first organic light-emitting diode OLED1, a second color filter layer 522 corresponding to the second organic light-emitting diode OLED2, and a third color filter layer 523 corresponding to the third organic light-emitting diode OLED3.

The first color filter layer 521 may be located in the 2-1^{th} opening 510OP1 of the light-blocking layer 510, the second color filter layer 522 may be located in the 2-2^{th} opening 510OP2, and the third color filter layer 523 may be located in the 2-3^{th} opening 510OP3. The first color filter layer 521 may have a color corresponding to light emitted from the first emission area EA1, the second color filter layer 522 may have a color corresponding to light emitted from the second emission area EA2, and the third color filter layer 523 may have a color corresponding to light emitted from the third emission area EA3. For example, when red light is emitted from the first emission area EA1, the first color filter layer 521 may be a red color filter layer, and when green light is emitted from the second emission area EA2, the second color filter layer 522 may be a green color filter layer. When blue light is emitted from the third emission area EA3, the third color filter layer 523 may be a light-transmitting layer including a transparent photosensitive resin. However, the disclosure is not limited thereto.

The overcoat layer 530 may be located on the color filter layer 520. The overcoat layer 530 is a light-transmitting layer that does not have a color in a visible band, and may provide a flat top surface and may cover an uneven portion generated while the color filter layer 520 and the light-blocking layer 510 are formed.

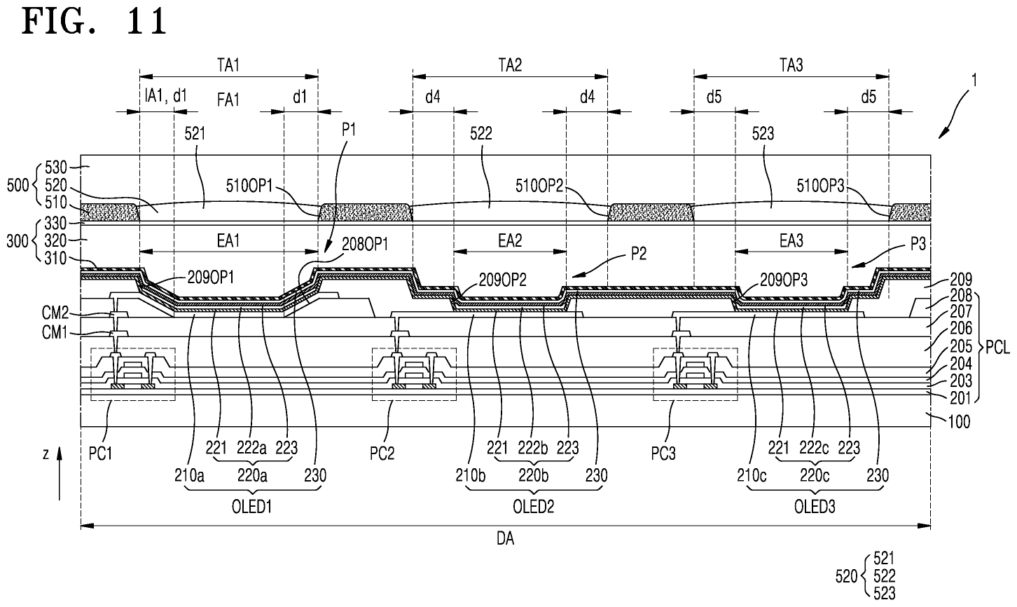

FIG. 11 is a cross-sectional view schematically illustrating a display apparatus according to an embodiment. FIG. 11 is similar to FIG. 10 except that the first bank layer 208 is spaced apart from the second pixel electrode 210b and the third pixel electrode 210c. A repeated description of the same or similar elements will be omitted, and a difference will be mainly described.

The first bank layer 208 may define the 1-1^{th} opening 208OP1 formed through the first bank layer 208. The first bank layer 208 may be located to correspond to the first sub-pixel P1. The first bank layer 208 may be spaced apart from the second sub-pixel P2 and the third sub-pixel P3. A side surface of the first bank layer 208 defining the 1-1^{th} opening 208OP1 may have an angle of about 15° to about 25°. A thickness of the first bank layer 208 may range from about 0.5 μm to about 2.3 μm.

The first bank layer 208 may be spaced apart from the second pixel electrode 210b and the third pixel electrode 210c. In other words, in a plan view, the first bank layer 208 may not overlap the second pixel electrode 210b and the third pixel electrode 210c.

The first organic light-emitting diode OLED1 may include the first pixel electrode 210a, the first intermediate layer 220a, and the counter electrode 230, the second organic light-emitting diode OLED2 may include the second pixel electrode 210b, the second intermediate layer 220b, and the counter electrode 230, and the third organic light-emitting diode OLED3 may include the third pixel electrode 210c, the third intermediate layer 220c, and the counter electrode 230.

The first pixel electrode 210a may be located to correspond to the 1-1^{th} opening 208OP1. The first pixel electrode 210a may be located on the second planarization layer 207 and the first bank layer 208, and the first pixel electrode 210a may be located to extend from a top surface of the first bank layer 208, through the side surface of the first bank layer 208 defining the 1-1^{th} opening 208OP1, to a top surface of the second planarization layer 207 exposed through the 1-1^{th} opening 208OP1. Accordingly, the first pixel electrode 210a may include an inclined surface located on the side surface of the first bank layer 208 and a flat surface located on the second planarization layer 207. The inclined surface of the first pixel electrode 210a may be inclined by about 15° to about 25° with respect to the flat surface of the first pixel electrode 210a. The first pixel electrode 210a may have a substantially concave shape. In a plan view, the 1-1^{th} distance d1 between an (outer) boundary of the inclined surface of the first pixel electrode 210a and a boundary of the flat surface of the first pixel electrode 210a may range from about 1 μm to about 5 μm.

The second pixel electrode 210b may be located on the second planarization layer 207, and may have only a flat surface. Likewise, the third pixel electrode 210c may be located on the second planarization layer 207, and may have only a flat surface.

The second bank layer 209 may cover edges of the first pixel electrode 210a, the second pixel electrode 210b, and the third pixel electrode 210c. The second bank layer 209 may define the first pixel opening 209OP1 overlapping the 1-1^{th} opening 208OP1, the second pixel opening 209OP2 exposing a central portion of the second pixel electrode 210b, and the third pixel opening 209OP3 exposing a central portion of the third pixel electrode 210c. The first pixel opening 209OP1 may define the first emission area EA1 of the first organic light-emitting diode OLED1, the second pixel opening 209OP2 may define the second emission area EA2 of the second organic light-emitting diode OLED2, and the third pixel opening 209OP3 may define the third emission area EA3 of the third organic light-emitting diode OLED3.

The light-blocking layer 510 may define the 2-1^{th} opening 510OP1 overlapping the first pixel opening 209OP1, the 2-2^{th} opening 510OP2 overlapping the second pixel opening 209OP2, and the 2-3^{th} opening 510OP3 overlapping the third pixel opening 209OP3. The 2-1^{th} opening 510OP1 may define the first transmissive area TA1 through which light emitted by the first organic light-emitting diode OLED1 is transmitted to the outside of the display apparatus 1, the 2-2^{th} opening 510OP2 may define the second transmissive area TA2 through which light emitted by the second organic light-emitting diode OLED2 is transmitted to the outside of the display apparatus 1, and the 2-3^{th} opening 510OP3 may define the third transmissive area TA3 through which light emitted by the third organic light-emitting diode OLED3 is transmitted to the outside of the display apparatus 1.

In an embodiment, a width of the 2-1^{th} opening 510OP1 of the light-blocking layer 510 may be substantially the same as a width of the first pixel opening 209OP1 of the second bank layer 209 within an error margin. On the other hand, a width of the 2-2^{th} opening 510OP2 may be greater than a width of the second pixel opening 209OP2, and a width of the 2-3^{th} opening 510OP3 may be greater than a width of the third pixel opening 209OP3. In other words, a width (or area) of the first transmissive area TA1 may be substantially the same as a width (or area) of the first emission area EA1 within an error margin, but a width (or area) of the second transmissive area TA2 may be greater than a width (or area) of the second emission area EA2 and a width (or area) of the third transmissive area TA3 may be greater than a width (or area) of the third emission area EA3. For example, in a plan view, a second distance d4 between a boundary of the second transmissive area TA2 and a boundary of the second emission area EA2 may range from about 3 μm to about 7 μm. Likewise, in a plan view, a third distance d5 between a boundary of the third transmissive area TA3 and a boundary of the third emission area EA3 may range from about 3 μm to about 7 μm.

Because each of the second pixel electrode 210b and the third pixel electrode 210c has only a flat surface, in order to ensure a lateral luminance, widths (or areas) of the second transmissive area TA2 and the third transmissive area TA3 may be greater than those of the second emission area EA2 and the third emission area EA3.

Although only the first pixel electrode 210a has an inclined surface in FIG. 11, the disclosure is not limited thereto. In another embodiment, the first bank layer 208 may be located to correspond to the first sub-pixel P1 and the second sub-pixel P2. The first bank layer 208 may further include a 1-2^{th} opening, and the second pixel electrode 210b may include an inclined surface located on a side surface of the first bank layer 208 and a flat surface located on the second planarization layer 207.

As described above, because only pixel electrodes of some sub-pixels include inclined surfaces, a change in a luminance of each sub-pixel according to a viewing angle may be adjusted. Accordingly, the color of the display apparatus 1 at a high viewing angle may be adjusted.

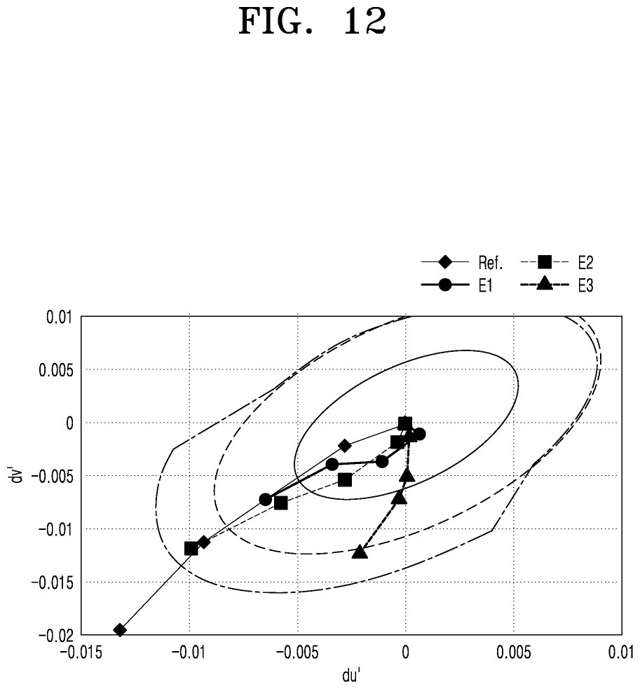

FIG. 12 is a graph illustrating a simulation result of a change in white color coordinates of display apparatuses according to a change in a viewing angle. FIG. 12 is obtained by measuring white color coordinates while changing a viewing angle by every 15° based on a direction perpendicular to a front surface of a display apparatus.

In sub-pixels included in a display apparatus of Comparative Example Ref, a pixel electrode had only a flat surface. In Experimental Example 1 E1, sub-pixels had an inclined surface and a flat surface, and a first distance between an (outer) boundary of the inclined surface of the pixel electrode and a boundary of the flat surface of the pixel electrode in a plan view was about 5 μm. In Experimental Example 2 E2, sub-pixels had an inclined surface and a flat surface, and a first distance between an (outer) boundary of the inclined surface of the pixel electrode and a boundary of the flat surface of the pixel electrode in a plan view was about 2 μm. In Experimental Example 3 E3, only a red sub-pixel had an inclined surface and a flat surface, and a green sub-pixel and a blue sub-pixel had only a flat surface. In Experimental Example 3 E3, in the red sub-pixel, a first distance between an (outer) boundary of the inclined surface of the pixel electrode and a boundary of the flat surface of the pixel electrode in a plan view was about 5 μm.

In Comparative Example Ref, it is found that as a viewing angle increases, white color coordinates change so that dv′ and du′ values have negative values. Accordingly, the display apparatus of Comparative Example has a bluish color at a high viewing angle.

In Experimental Example 1 E1 and Experimental Example 2 E2, it is found that a change in white color coordinates according to an increase in a viewing angle is smaller than that in Comparative Example Ref. Also, a change in white color coordinates of Experimental Example 1 E1 in which the first distance was about 5 μm is smaller than a change in white color coordinates of Experimental Example 2 E2 in which the first distance was about 2 μm.

In Experimental Example 3 E3, it is found through simulation that, because only the pixel electrode of the red sub-pixel had an inclined surface, a change value of du′ according to an increase in a viewing angle is large. Accordingly, because a change in white color coordinates according to an increase in a viewing angle is smaller than that in Comparative Example Ref and a change trajectory of white color coordinates is improved, a color degradation phenomenon where the display apparatus looks bluish at a high viewing angle may be reduced.

According to an embodiment, as described above, there may be provided a display apparatus capable of providing a high-quality image even when viewed in a direction oblique to a front surface of the display apparatus. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus comprising:
a substrate;
a pixel circuit layer located on the substrate and comprising at least one thin-film transistor, a planarization layer located on the at least one thin-film transistor, and a first bank layer located on the planarization layer and defining a first opening;
a display element comprising a pixel electrode located to correspond to the first opening, a counter electrode, and an emission layer located between the pixel electrode and the counter electrode;
a second bank layer located between the pixel electrode and the counter electrode to cover an edge of the pixel electrode and defining a pixel opening overlapping the first opening; and
a light-blocking layer located on the display element and defining a second opening overlapping the pixel opening,
wherein the pixel electrode comprises an inclined surface located on a side surface of the first bank layer defining the first opening and a flat surface located on a top surface of the planarization layer exposed through the first opening,
wherein the inclined surface of the pixel electrode is inclined by 15° to 25° with respect to the flat surface of the pixel electrode.

2. The display apparatus of claim 1, wherein, in a plan view, a distance between a boundary of the inclined surface of the pixel electrode and a boundary of the flat surface of the pixel electrode ranges from 1 μm to 5 μm.

3. The display apparatus of claim 1, wherein a thickness of the first bank layer ranges from 0.5 μm to 2.3 μm.

4. The display apparatus of claim 1, wherein a width of the second opening is the same as a width of the pixel opening.

5. The display apparatus of claim 1, further comprising a color filter layer located on the display element to correspond to the second opening.

6. A display apparatus comprising:
a substrate;
a pixel circuit layer located on the substrate and comprising at least one thin-film transistor, a planarization layer located on the at least one thin-film transistor, and a first bank layer located on the planarization layer and defining a 1-1^{th} opening;
a first display element comprising a first pixel electrode located to correspond to the 1-1^{th} opening, a counter electrode, and a first emission layer located between the first pixel electrode and the counter electrode;
a second display element spaced apart from the first pixel electrode, and comprising a second pixel electrode, the counter electrode, and a second emission layer located between the second pixel electrode and the counter electrode;
a second bank layer covering an edge of each of the first pixel electrode and the second pixel electrode, and defining a first pixel opening corresponding to the first pixel electrode and a second pixel opening corresponding to the second pixel electrode; and
a light-blocking layer located on the first display element and the second display element, and defining a 2-1^{th} opening overlapping the first pixel opening and a 2-2^{th} opening overlapping the second pixel opening,
wherein the first pixel electrode comprises an inclined surface located on a side surface of the first bank layer defining the 1-1^{th} opening and a flat surface located on a top surface of the planarization layer exposed through the 1-1^{th} opening, and
wherein the inclined surface of the first pixel electrode is inclined by 15° to 25° with respect to the flat surface of the first pixel electrode.

7. The display apparatus of claim 6, wherein, in a plan view, a distance between a boundary of the inclined surface of the first pixel electrode and a boundary of the flat surface of the first pixel electrode ranges from 1 μm to 5 μm.

8. The display apparatus of claim 6, wherein a thickness of the first bank layer ranges from 0.5 μm to 2.3 μm.

9. The display apparatus of claim 6, wherein a width of the 2-1^{th} opening is same as a width of the first pixel opening.

10. The display apparatus of claim 6, wherein the first bank layer further defines a 1-2^{th} opening corresponding to the second pixel electrode,
wherein the second pixel electrode comprises an inclined surface located on a side surface of the first bank layer defining the 1-2^{th} opening and a flat surface located on a top surface of the planarization layer exposed through the 1-2^{th} opening.

11. The display apparatus of claim 10, wherein, in a plan view, a 1-1^{th} distance between a boundary of the inclined surface of the first pixel electrode and a boundary of the flat surface of the first pixel electrode is different from a 1-2^{th} distance between a boundary of the inclined surface of the second pixel electrode and a boundary of the flat surface of the second pixel electrode.

12. The display apparatus of claim 11, wherein, in a plan view, the 1-2^{th} distance between the boundary of the inclined surface of the second pixel electrode and the boundary of the flat surface of the second pixel electrode ranges from 1 μm to 5 μm.

13. The display apparatus of claim 10, wherein a width of the 2-2^{th} opening is same as a width of the second pixel opening.

14. A display apparatus comprising:
a substrate;
a pixel circuit layer located on the substrate and comprising at least one thin-film transistor, a planarization layer located on the at least one thin-film transistor, and a first bank layer located on the planarization layer and defining a 1-1^{th} opening;
a first display element comprising a first pixel electrode located to correspond to the 1-1^{th} opening, a counter electrode, and a first emission layer located between the first pixel electrode and the counter electrode;
a second display element located on the planarization layer to be spaced apart from the first pixel electrode, the second display element comprising a second pixel electrode, the counter electrode, and a second emission layer located between the second pixel electrode and the counter electrode;
a second bank layer covering an edge of each of the first pixel electrode and the second pixel electrode, and defining a first pixel opening corresponding to the first pixel electrode and a second pixel opening corresponding to the second pixel electrode; and
a light-blocking layer located on the first display element and the second display element and defining a 2-1^{th} opening overlapping the first pixel opening and a 2-2^{th} opening overlapping the second pixel opening,
wherein the first pixel electrode comprises an inclined surface located on a side surface of the first bank layer defining the 1-1^{th} opening and a flat surface located on a top surface of the planarization layer exposed through the 1-1^{th} opening, and
wherein the second pixel electrode comprises only a flat surface located on a top surface of the planarization layer.

15. The display apparatus of claim 14, wherein the inclined surface of the first pixel electrode is inclined by 15° to 25° with respect to the flat surface of the first pixel electrode.

16. The display apparatus of claim 14, wherein, in a plan view, a distance between a boundary of the inclined surface of the first pixel electrode and a boundary of the flat surface of the first pixel electrode ranges from 1 μm to 5 μm.

17. The display apparatus of claim 14, wherein a thickness of the first bank layer ranges from 0.5 μm to 2.3 μm.

18. The display apparatus of claim 14, wherein a width of the 2-1^{th} opening is same as a width of the first pixel opening.

19. The display apparatus of claim 14, wherein the first bank layer is spaced apart from the second pixel electrode.

20. The display apparatus of claim 14, wherein a width of the 2-2^{th} opening is greater than a width of the second pixel opening.
